(19) United States
(12) Patent Application Publication
(10) Pub. No.: US 2013/0015856 A1
(43) Pub. Date: Jan. 17, 2013

(54) MRI MICROSCOPE ADAPTER

(71) Applicant: Irving N. WEINBERG, Bethesda, MD (US)

(72) Inventor: Irving N. WEINBERG, Bethesda, MD (US)

(73) Assignee: WEINBERG MEDICAL PHYSICS LLC, Bethesda, MD (US)

(21) Appl. No.: 13/543,056

(22) Filed: Jul. 6, 2012

Related U.S. Application Data
(60) Provisional application No. 61/506,214, filed on Jul. 11, 2011.

(51) Int. Cl. G01R 33/48

(52) U.S. Cl. 324/309

(57) ABSTRACT

Disclosed embodiments pertain to an inventive method and apparatus that confers the ability to image using Magnetic Resonance Imaging (MRI) to an optical microscope. Through implementation of the disclosed embodiments, it is possible to collect spectroscopic information as well as anatomic information using the objective structure and/or MRI-enabled stage.

### CROSS-REFERENCE TO RELATED APPLICATION(S)

The present application claims the benefit of priority to Provisional Patent Application No. 61/506,214 filed Jul. 11, 2011, the contents of which are incorporated herein by reference in their entirety.

### FIELD OF THE INVENTION

Disclosed embodiments pertain to an inventive method and apparatus that confers the ability to image using Magnetic Resonance Imaging (MRI) to an optical microscope.

### SUMMARY

The following presents a simplified summary in order to provide a basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to the more detailed description below.

Disclosed embodiments pertain to an inventive method and apparatus that confers the ability to image using Magnetic Resonance Imaging (MRI) to an optical microscope.

### BRIEF DESCRIPTION OF THE DRAWINGS

A more compete understanding of the present invention and the utility thereof may be acquired by referring to the following description in consideration of the accompanying drawings, in which like reference numbers indicate like features, and wherein:

FIG. 1 is an illustration of one disclosed embodiment of the MRI microscope adapter provided in combination with a conventional optical microscope in accordance with at least one embodiment of the invention.

FIG. 2 is an expanded view of the MRI objective lens in accordance with at least one embodiment of the invention.

FIG. 3 is an expanded view of the MRI objective lens in accordance with a separate embodiment of the invention.

FIG. 4 is an expanded view of the MRI objective lens in accordance with a separate embodiment of the invention.

FIG. 5 illustrates one example of a method for imaging a sample in accordance with at least one disclosed embodiment.

### DETAILED DESCRIPTION

The description of specific embodiments is not intended to be limiting of the present invention. To the contrary, those skilled in the art should appreciate that there are numerous variations and equivalents that may be employed without departing from the scope of the present invention. Those equivalents and variations are intended to be encompassed by the present invention.

In the following description of various invention embodiments, reference is made to the accompanying drawings, which form a part hereof, and in which is shown, by way of illustration, various embodiments in which the invention may be practiced. It is to be understood that other embodiments may be utilized and structural and functional modifications may be made without departing from the scope and spirit of the present invention.

Moreover, it should be understood that various connections are set forth between elements in the following description; however, these connections in general, and, unless otherwise specified, may be either direct or indirect, either permanent or transitory, and either dedicated or shared, and that this specification is not intended to be limiting in this respect.

Disclosed embodiments pertain to an inventive method and apparatus that confers the ability to image an object using magnetic resonance imaging (MRI) to an optical microscope. Alternatively, when chemical information about the object is required, the invention permits the collection of such information through magnetic resonance spectroscopy (MRS). Through implementation of the disclosed embodiments, it is possible to collect spectroscopic information as well as anatomic information using the objective structure and/or MRI-enabled or MRS-enabled stage. For the purpose of this disclosure, the objective conferring MRI or MRS capability to the microscope is referred to as MRI, consistent with the practice in the MRI industry (in which a single MRI instrument may be used to perform imaging and/or spectroscopy). It is understood that in this invention disclosure, the term magnetic resonance is used broadly, referring to signals from protons, electrons, and/or other particles.

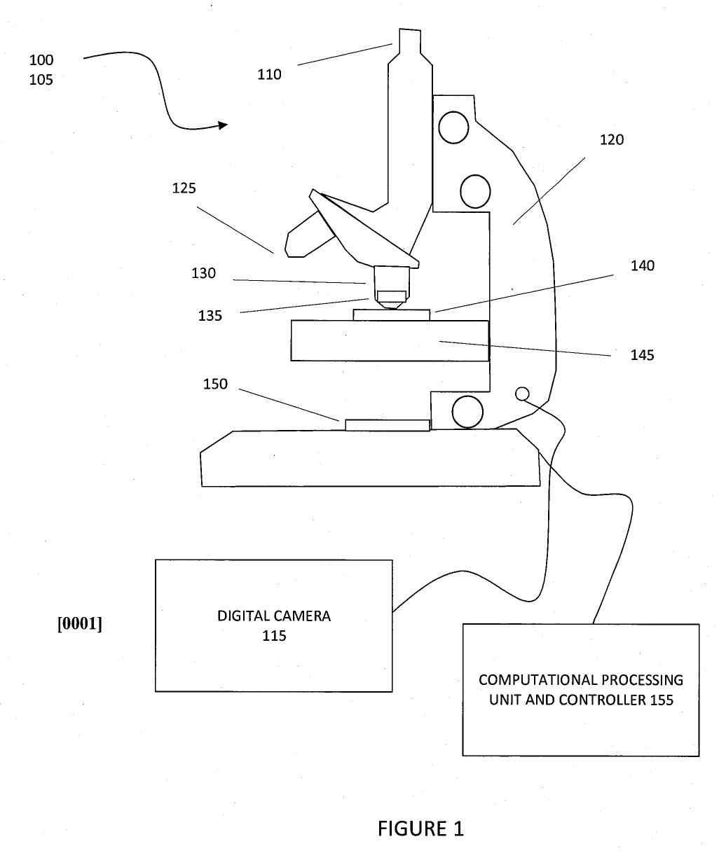

FIG. 1 is an illustration of one disclosed embodiment of the MRI microscope adapter 100 provided in combination with a conventional optical microscope 105.

The microscope 105 may be, for example, but not limited to a compound microscope that uses lenses and light to enlarge an image of a sample/specimen. Accordingly, the microscope 105 may have two systems of lenses for greater magnification, the ocular, or eyepiece lens 110 that one looks into, and the objective lens 135, or the lens closest to the object. It should be understood that the term “objective lens” generally refers to and encompasses any structure that physically approaches an object or sample in order to assist in providing information about the sample or sample holder 140.

As shown in FIG. 1, the microscope 105 includes an eyepiece 110. That eyepiece is optionally coupled to a digital camera 115 to record the data generated by viewing through the eyepiece 110. The microscope 105 also includes an arm 120 that supports the components of the microscope 105 and connects them to the base of the microscope.

In accordance with at least one embodiment, the conventional optical objective lens 125 is one of several objective lenses, each of which includes a variety of lens elements that confer various degrees of magnification to microscope 105. In accordance with at least one embodiment, optical objective lens 125 can be swung out of the optical path of the optical microscope 105 so as to enable an MRI imaging component to be provided, or to permit a different objective lens 125 of different optical magnification to be employed.

Also included is an illumination element 145 which may be included or be implemented as a mirror or other source of light (whether visible or not); thus, it should be understood that illumination is meant to be general, including laser sources and/or elements required for single-photon or dual-photon, or confocal microscopy, or other forms of microscopy. A mirror may be used to reflect light from an external light source up through the bottom of the stage. Alternatively, a steady light source may be used in place of a mirror.

Conventional objective lenses usually include three or four objective lens elements on a microscope. They almost always consist of 4×, 10×, 40× and 100× powers. When coupled with a 10× (most common) eyepiece lens, the total magnifications of 40× (4× times 10×), 100×, 400× and 1000× is provided. The microscope may also optionally include chromatic, parcentered, parfocal lenses and a condenser lens (which focuses light onto the specimen)

In accordance with at least one embodiment, the MRI microscope adapter 100 includes an MRI-enabled objective lens 130 which replaces the conventional optical objective lens. The MRI-enabled objective lens 130 includes one or more conventional optical objective elements as well as one or more coils 135 within or attached to the MRI-enabled objective lens 130. The coil 135 is (are) in close proximity to a sample and/or sample holder 140.

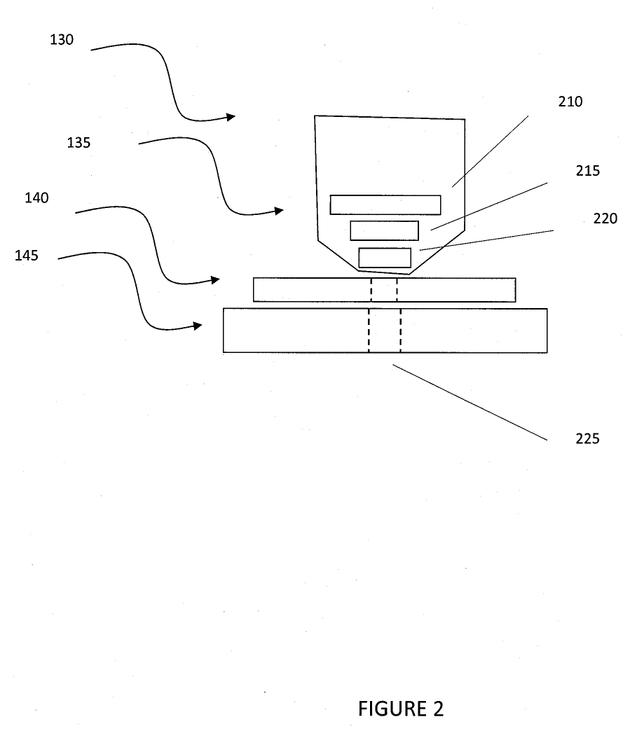

FIG. 2 is an expanded illustration of an embodiment of the MRI-enabled objective lens 130, coil apparatus 135, sample or sample holder 140, and stage 145, which provides magnetic resonance images of the object of interest (i.e., sample or sample-holder 140) but which do not simultaneously provide an optical image of the object of interest.

In FIG. 2, coil apparatus 135 is shown to comprise planar gradient coil assembly 210 and RF coil assembly 215. Planar gradient coil assembly 210 may comprise two- or three-dimensional gradient coils, and may include shim functionality. Alternatively an additional coil and/or permanent magnet 220 may be present in the objective structure to provide shim functionality and/or to establish a uniform magnetic field that is present while the MRI-enabled objective 130 is in close proximity to sample or sample-holder 140. RF assembly 215 may either comprise separate transmit and receive coils or coils that combine both functions. Optically-transparent sections of sample-holder 140 and stage 145 are denoted as feature 225 in FIG. 2.

It is understood that power supplies and connecting cables attach to the various components of the MRI-enabled objective lens. It is also understood that currents through gradient coil assembly 210 and/or RF coil assembly 215 may be pulsed in order to collect images. It is also understood that shim coil and/or permanent magnet 220 may provide pulsed or static magnetic fields.

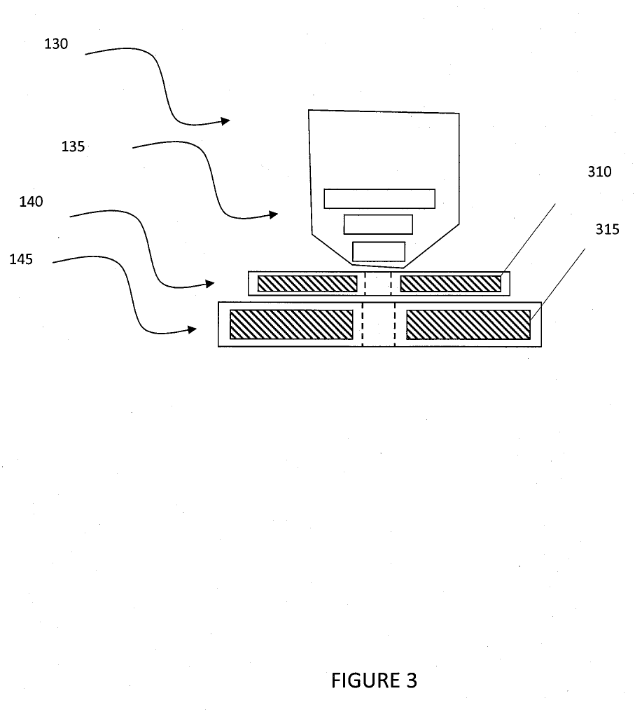

FIG. 3 is an expanded illustration of an embodiment of the MRI-enabled objective lens 130, which provides magnetic resonance images of the object of interest (i.e., sample or sample-holder 140). In FIG. 3, some or all of the functions of gradient coil assembly 210 and/or RF coil assembly 215 are provided through permanent or electromagnetic structures 310 and 315 embedded in sample-holder 140 and/or stage 145, respectively.

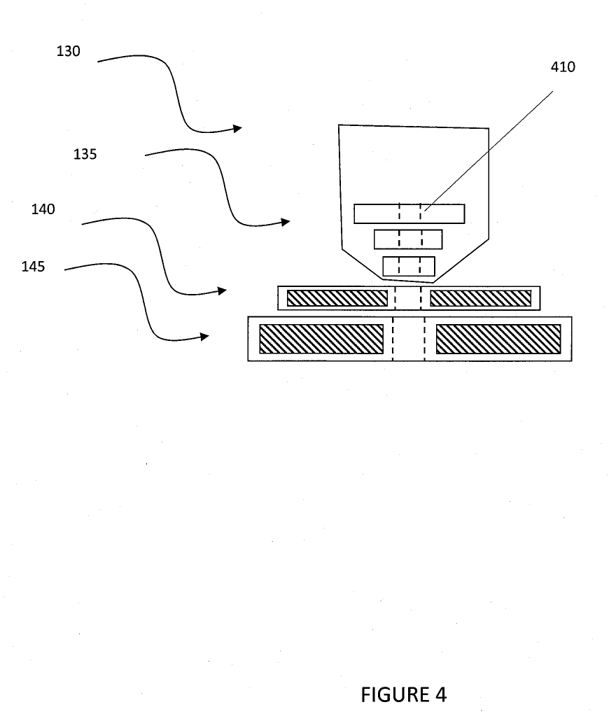

FIG. 4 is an expanded illustration of an embodiment of the MRI-enabled objective lens 130, which provides magnetic resonance images of the object of interest (i.e., sample or sample-holder 140) and which may simultaneously provide an optical image of the object of interest, as a result of optically-transparent sections 410 of the components comprising coils 135.

Note, in accordance with at least one other embodiment, the MRI imaging component may include an MRI objective lens that is actually separate from the optical objective lens (rather that being combined to provide an MRI-enabled objective lens) and may include one or more conventional optical objective elements as well as one or more coils within or attached to the MRI objective lens. Thus, the coil(s) is (are) in close proximity to a sample or sample holder 140.

Likewise, it should be understood that the term coil is used herein to refer in general to any set of electrical conductors arrayed to create an electromagnetic field.

In accordance with at least one disclosed embodiment, the MRI-enabled objective structure may be equipped with a radio frequency (RF) coil that is brought in close proximity to the sample to be imaged. Accordingly, it is possible to retain the optical elements of the objective structure and also to include the RF coil in such a manner that it does not always interfere with the optical path of light through the sample to be imaged.

Moreover, in accordance with at least one disclosed embodiment, a gradient coil is also added to the RF coil that resides on, or replaces, the MRI-enabled objective lens in order to form the MRI-enabled objective structure. In such an embodiment, the stage of the optical microscope may contain (or be replaced by) coils and/or permanent magnets that establish magnetic fields. Such magnetic fields, in turn, introduce at least one magnetic field gradient, which may be used to implement imaging of the sample. Thus, the term “MRI-enabled stage” should be understood to refer generally to and encompass an optical microscope stage.

In accordance with at lest one embodiment, the gradient coil added to the objective structure adds to, or replaces, one or more of the coils on the stage.

In accordance with at least one embodiment, it is possible to employ coils used to create a gradient field without the need for a separate apparatus to create a static field.

In accordance with at least one embodiment, it is possible to employ superconductors in the coils.

In accordance with the disclosed embodiments, the MRI microscope adapter 100 also includes or is coupled to one or more computational processing units (CPUs) and/or controllers 155 that operate under the control of one or more software algorithms (stored, for example, on computer readable media, to enable and control operation of at least some of the aforementioned components of the MRI microscope adapter 100 and/or the optical microscope 105. Such CPUs and/or controllers 155 may be implemented in one or more general purpose or special purpose computers that may be coupled to and/or include memory for storing software that enables superimposing, mapping, enlarging, and/or analyzing the electronically on digital representations of the optical image or images generated by the microscope. The controllers 155 may also include such software algorithms configured to control operation and/or positioning of the coils 135 and positioning of the stage 145 if positioning may be implemented using motors or the like (not shown). Furthermore, the coil(s) 135 and stage 145 may be connected or coupled to electronic equipment, e.g., including amplifiers, digitizers, power sources, and other computer implemented equipment and peripherals such as printers), as needed to create, record and analyze optical and MRI image data.

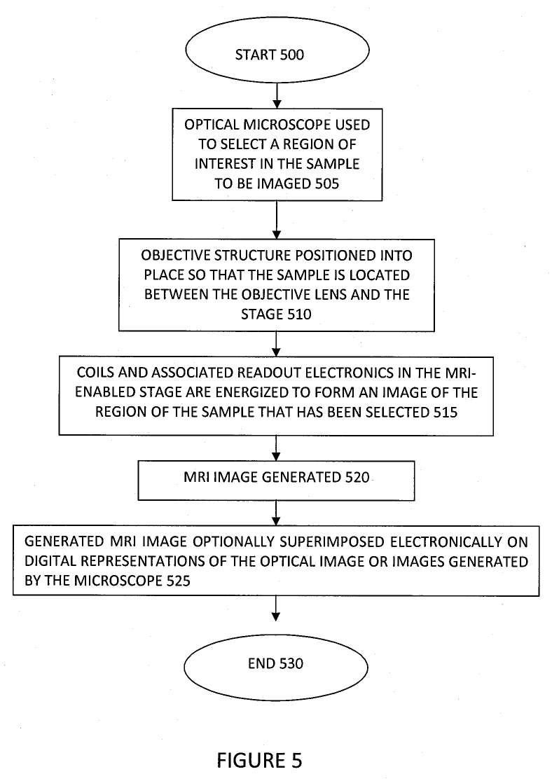

FIG. 5 illustrates one example of a method for imaging a sample in accordance with at least one disclosed embodiment. As shown in FIG. 5, the method begins at 500 and control proceeds to 505, at which the optical microscope is used to select a region of interest in the sample to be imaged. Subsequently, at 510, the MRI-enabled objective structure is positioned into place so that the sample is located between the objective lens and the stage. Then, at 515, the coils and associated readout electronics in the MRI-enabled stage are energized to form an image of the region of the sample that has been selected. Control then proceeds to 520, at which an MRI image is generated or MRS data is collected. Control then proceeds to 525 at which the generated MRI image is optionally superimposed electronically on digital representations of the optical image or images generated by the microscope. Control then proceeds to 530, at which the operations end.

Disclosed embodiments of the MRI microscope are inventive over conventional MRI microscopes in various ways. For example, conventional MRI microscopes have employed small RF and/or gradient coils in close proximity to a sample, but have relied on a large magnet to create an environment that would enable MRI microscopy. An example of such a use is the publication in the Journal of Magnetic Resonance, volume 200, pages 38-48, in 2009, by Andrey V. Demyanenko, Lin Zhao, Yun Kee, Shuyi Nie, Scott E Fraser, and J Michael Tyszka, entitled “A uniplanar three-axis gradient set for in vivo magnetic resonance microscopy.”

Demvanenko et al. disclosed an optimized uniplanar magnetic resonance gradient design for MR imaging applications. That design decreased the size of the uniplanar gradient set to improve gradient uniformity for high gradient efficiency and slew rate. Demvanenko et al.'s design provides a three-axis, target-field optimized uniplanar gradient coil design that is designed for microscopy in horizontal bore magnets, e.g., a horizontal bore 7 Tesla magnet. As a result, many of the design considerations relate to improvements for cooling and insulation for reducing sample heating for the three axis, target-field optimized uniplanar gradient coil design.

However, disclosed embodiments of the MRI microscope replace the large magnet with a small stage, which fits in an optical microscope and facilitates correlation between the optical and MRI images and/or measurements. As a result of the elimination of the large magnets, the fundamentally different approach provided by the presently disclosed embodiments do not require compensation or design to reduce the resulting heating of samples that comes along with use of such magnets. It should be understood, however, that various components and/or techniques disclosed in that publication may be incorporated in combination with the presently disclosed embodiments. Accordingly, that publication is incorporated by reference in its entirety.

Another conventional MRI system is the single-sided MRI system, an example of which being published by Jeffrey L Paulsen, Louis S Bouchard, Dominic Graziani, Bernhard Blümich, and Alexander Pines, in the Proceedings of the National Academy of Sciences, volume 105, number 52, pages 20601-20604, entitled “Volume-selective magnetic resonance imaging using an adjustable, single-sided, portable sensor.” It should be understood, however, that various components and/or techniques disclosed in that publication may be incorporated in combination with the presently disclosed embodiments. Accordingly, that publication is incorporated by reference in its entirety.

However, disclosed embodiments of the MRI microscope differ and improve upon these conventional systems as well because the current innovation integrates MRI components within an optical microscope, and thereby facilitates and enables correlation between optical data generated by the optical components of the microscope and MRI images and/or measurements generated by the MRI-related components.

While this invention has been described in conjunction with the specific embodiments outlined above, it is evident that many alternatives, modifications and variations will be apparent to those skilled in the art. Accordingly, the various embodiments of the invention, as set forth above, are intended to be illustrative, not limiting. Various changes may be made without departing from the spirit and scope of the invention.

For example, it should be understood that the disclosed embodiments may be configured as a kit that can convert a commercially available and/or conventional optical microscope to the MRI-enabled microscope as described in this disclosure.

Moreover, it should be understood that the MRI-enabled microscope adapter and resulting MRI-enabled microscope are not limited to use with a compound optical microscope or the like. Therefore, MRI-imaging adapters may be used with various other types of microscopes as well.

Furthermore, in accordance with at least one embodiment, it is possible to replace the RF coil with a sensitive magnetometer.

Additionally, it should be understood that the functionality described in connection with various described components of various invention embodiments may be combined or separated from one another in such a way that the architecture of the invention is somewhat different than what is expressly disclosed herein. Moreover, it should be understood that, unless otherwise specified, there is no essential requirement that methodology operations be performed in the illustrated order; therefore, one of ordinary skill in the art would recognize that some operations may be performed in one or more alternative order and/or simultaneously.

Various components of the invention may be provided in alternative combinations operated by, under the control of or on the behalf of various different entities or individuals.

Further, it should be understood that, in accordance with at least one embodiment of the invention, system components may be implemented together or separately and there may be one or more of any or all of the disclosed system components. Further, system components may be either dedicated systems or such functionality may be implemented as virtual systems implemented on general purpose equipment via software implementations.

As a result, it will be apparent for those skilled in the art that the illustrative embodiments described are only examples and that various modifications can be made within the scope of the invention as defined in the appended claims.

What is claimed is:

1. An apparatus comprising:
means for obtaining an optical microscopic image of a sample; and
means for analyzing the sample using magnetic resonance; and
where the sample may be left unchanged in position between the collection of optical and magnetic resonance information.

2. The apparatus of claim 1, wherein the means for analyzing the sample using magnetic resonance is located in or near an objective structure that is configured to be rotated into place near the sample by an operator.

3. The apparatus of claim 2, wherein an optical path through the objective structure remains unobstructed by the means for analyzing when the means for analyzing is rotated into place near the sample.

4. The apparatus of claim 1, where one or more of the components for analyzing the sample using magnetic resonance is located in or near a stage that is located near the sample.

5. The apparatus of claim 1, wherein the means for obtaining an optical microscopic image of a sample includes a compound microscope that uses lenses and light to enlarge an image of a sample/specimen.

6. The apparatus of claim 1, wherein the means for obtaining an optical microscopic image of a sample includes at least one optical objective lens and wherein the means for analyzing the sample using magnetic resonance includes at least one coil coupled to the optical objective lens.

7. The apparatus of claim 6, wherein the at least one coil is located proximate to the sample.

8. The apparatus of claim 1, wherein the means for analyzing the sample using magnetic resonance includes at least one coil located in proximate to the sample.

9. The apparatus of claim 1, wherein the at least one coil is a radio frequency coil that is excited to create a magnetic field.

10. The apparatus of claim 9, wherein the at least one coils includes a gradient coil that resides on, or replaces, the optical objective lens.

11. The apparatus of claim 10, wherein the apparatus further comprises a stage that includes at least one coil and/or permanent magnet that establishes a magnetic field.

12. A method for collecting a microscopic optical image and a microscopic magnetic resonance image of a sample without moving the sample using an apparatus comprising means for obtaining an optical microscopic image of a sample, and means for analyzing the sample using magnetic resonance, the method comprising:
using the optical microscope to select a region of interest in the sample to be imaged;
positioning an objective structure into place so that the sample is located between an MRI-enabled objective lens and a stage;
energizing at least one coil and associated readout electronics; and
generating MRI image data for the sample.

13. The method of claim 12, further comprising superimposing the MRI image data on digital representations of the optical image or images generated by the microscope.

14. The method of claim 13, wherein the at least one coil is located in or near the objective structure and is configured to be rotated into place near the sample by an operator.

15. The method of claim 12, wherein the optical path through the objective structure remains unobstructed throughout the method.

16. The method of claim 12, further comprising analyzing the sample using magnetic resonance

17. The method of claim 16, wherein one or more components for analyzing the same using magnetic resonance is located in or near a stage that is located near the sample.
